(19) United States
(12) Patent Application Publication
(10) Pub. No.: US 2025/0113712 A1
(43) Pub. Date: Apr. 3, 2025

(54) DISPLAY PANEL AND DISPLAY APPARATUS

(71) Applicants: Chengdu BOE Optoelectronics Technology Co., Ltd., Chengdu, Sichuan (CN); BOE Technology Group Co., Ltd., Beijing (CN)

(72) Inventors: Xiang LUO, Beijing (CN); Jianpeng WU, Beijing (CN); Miao WANG, Beijing (CN); Zhiliang JIANG, Beijing (CN); Ju MEI, Beijing (CN); Hong CHEN, Beijing (CN); Ge NIU, Beijing (CN); Dengyu WANG, Beijing (CN); Yanli WANG, Beijing (CN); Xuan TAO, Beijing (CN)

(73) Assignees: Chengdu BOE Optoelectronics Technology Co., Ltd., Chengdu, Sichuan (CN); BOE Technology Group Co., Ltd., Beijing (CN)

(21) Appl. No.: 18/832,162

(22) PCT Filed: Nov. 25, 2022
(86) PCT No.: PCT/CN2022/134358

§ 371 Date: Jul. 23, 2024

(51) Int. Cl. H10K 59/131; H10K 59/40

(52) U.S. Cl. CPC H10K 59/131; H10K 59/40

(57) ABSTRACT

A display panel, having a display area and a peripheral area outside the display area, includes: a driving backplane, comprising a substrate and a transistor layer, a first conductive layer, a first planarization layer and a second conductive layer sequentially provided in a direction away from the substrate; and a light-emitting device, provided on a side of the second conductive layer away from the substrate and located in the display area; wherein the light-emitting device comprises a first electrode, a light-emitting layer and a second electrode stacked in sequence in the direction away from the substrate; the first electrode is connected to at least one of the transistors through the second conductive layer, and the second electrode is connected to the second conductive line.

### TECHNICAL FIELD

This disclosure relates to the field of display technology, and in particular to a display panel and a display device.

### BACKGROUND

Display panels have become an indispensable part of mobile phones, tablet computers, televisions and other terminal devices. Display panels using organic light-emitting diodes are widely used. Existing display panels have high power consumption and low screen- to-body ratio, which are not conducive to improving resolution.

It is to be noted that the above information disclosed in this background section is only for enhancing understanding the context of the disclosure and, therefore, may contain information that does not form the prior art that is already known to those skilled in the art.

### SUMMARY

This disclosure provides a display panel and a display device.

According to an aspect of this disclosure, there is provided a display panel having a display area and a peripheral area outside the display area; the display panel includes:
a driving backplane, including a substrate and a transistor layer, a first conductive layer, a first planarization layer and a second conductive layer sequentially provided in a direction away from the substrate; where the transistor layer includes a plurality of transistors; the first conductive layer includes a first conductive line at least partially located in the display area; the second conductive layer includes a power line and a second conductive line spaced from each other, and both the power line and the second conductive line are at least partially located in the display area; the second conductive line is connected to the first conductive line through a plurality of contact holes penetrating the first planarization layer; the power line is configured to transmit a first power signal, and the first conductive line and the second conductive line are configured to transmit a second power signal; the contact holes are arranged in a row direction and a column direction, a spacing between any two adjacent contact holes in the row direction is a first hole spacing, and a spacing between any two adjacent contact holes in the column direction is a second hole spacing; some contact holes have the same first hole spacing in at least two rows of contact holes, and some contact holes have the same second hole spacing in at least two columns of contact holes; and
a light-emitting device, provided on a side of the second conductive layer away from the substrate and located in the display area; where the light-emitting device includes a first electrode, a light-emitting layer and a second electrode stacked in sequence in the direction away from the substrate; the first electrode is connected to at least one of the transistors through the second conductive layer, and the second electrode is connected to the second conductive line.

In some exemplary embodiments of this disclosure, at least some of the contact holes are divided into a plurality of hole groups, and the respective hole groups are arranged in a plurality of rows along the column direction;
one of the hole groups includes some of the contact holes, and the contact holes in the one of the hole groups are arranged along a zigzag track.

In some exemplary embodiments of this disclosure, the contact holes in the one of the hole groups are arranged along a V-shaped track.

In some exemplary embodiments of this disclosure, the V-shaped track includes two intersecting sides, and both of the two sides intersect with the row direction and the column direction; and the contact holes in the one of the hole groups are symmetrically distributed along the two sides.

In some exemplary embodiments of this disclosure, the contact holes in the one of the hole groups are distributed into a plurality of rows along the column direction, and a number of contact holes in one row in the one of the hole groups is two;
a contact hole in k-th row of a hole group in n-th row and i-th column is located in a same row as two contact holes in 1^{st} row of a hole group in (n+1)-th row and i-th column, and the contact hole in the k-th row of the hole group in the n-th row and i-th column is located between the two contact holes in the 1^{st} row of the hole group in the (n+1)-th row and i-th column;
where n, i and k are all positive integers, and k is greater than 1.

In some exemplary embodiments of this disclosure, at least some of the contact holes are arranged along a track formed by a plurality of radially distributed straight lines intersecting at a same intersection.

In some exemplary embodiments of this disclosure, each of the straight lines is provided with multiple ones of the contact holes, and numbers of contact holes on each of the straight lines are the same.

In some exemplary embodiments of this disclosure, the first hole spacings of contact holes in a same row are the same.

In some exemplary embodiments of this disclosure, the second hole spacings of contact holes in a same column are the same.

In some exemplary embodiments of this disclosure, the display panel further includes:
a touch layer, provided on a side of the light-emitting device away from the substrate; where the touch layer includes a plurality of touch electrodes, and the touch electrodes are in a grid structure formed by a plurality of grid lines;
where at least some of the contact holes overlap with the grid lines.

In some exemplary embodiments of this disclosure, the touch electrodes include a plurality of first touch electrodes and a plurality of second touch electrodes, the respective first touch electrodes are spaced apart along the row direction, and one of the first touch electrodes includes a plurality of first electrode blocks spaced apart along the column direction and a connecting bridge connecting any adjacent two of the first electrode blocks; the respective second touch electrodes are spaced apart along the column direction, and one of the second touch electrodes includes a plurality of second electrode blocks connected in series along the row direction; one of the connecting bridges is arranged crosswise with one of the second touch electrodes; the first electrode blocks and the second electrode are located in a same electrode layer; and the connecting bridges are located on one side of the electrode layer;
the touch layer further includes a touch insulating layer located between the connecting bridges and the electrode layer, and the connecting bridges are connected to the first electrode blocks through a via hole penetrating the touch insulating layer.

In some exemplary embodiments of this disclosure, an orthographic projection of a contact hole on the substrate is located within an orthographic projection, on the substrate, of a grid line overlapping with the contact hole.

In some exemplary embodiments of this disclosure, the orthographic projection of the contact hole on the substrate is a polygon, and at least one side of the polygon is parallel to a side of the orthographic projection, on the substrate, of the grid line, where the polygon is located at the grid line.

In some exemplary embodiments of this disclosure, the orthographic projection of the contact hole on the substrate is a square, and a side length of the square is smaller than a width of the grid line.

In some exemplary embodiments of this disclosure, the first electrode blocks and the second electrode blocks are located on a side of the connecting bridges away from the substrate;
grid lines corresponding to the connecting bridges are connecting lines, and grid lines corresponding to the first electrode blocks and the second electrode blocks are electrode lines; at least some adjacent ones of the connecting lines are connected through a connecting intersection, and a width of the connecting intersection is greater than a width of the connecting line connected to the connecting intersection; at least some adjacent ones of the electrode lines are connected through an electrode intersection, and a width of the electrode intersection is greater than a width of the electrode line connected to the electrode intersection; the connecting intersection is connected to the electrode intersection through the via hole;
one of the contact holes overlaps with the connecting intersection and the electrode intersection.

In some exemplary embodiments of this disclosure, the second conductive layer further includes a data line; the data line, the power line and the second conductive line all extend along the column direction and are spaced apart along the row direction;
the driving backplane includes a plurality of pixel circuits distributed along the row direction and the column direction, and the pixel circuit includes a plurality of the transistors;
one column of the pixel circuits overlaps with and is connected to the data line and the power line;
the data line and the power line connected to the pixel circuits in a same column form a line group, and at least some of the second conductive lines and the line group are alternately distributed along the row direction.

According to an aspect of this disclosure, a display device is provided and includes any one of the display panels described above.

It is to be understood that both the foregoing general description and the following detailed description are exemplary and explanatory only and are not restrictive of this disclosure.

### BRIEF DESCRIPTION OF THE DRAWINGS

The accompanying drawings, which are incorporated in and constitute a part of this specification, illustrate embodiments consistent with the disclosure and together with the description serve to explain the principles of the disclosure. Apparently, the drawings in the following description are only some embodiments of this disclosure, and those skilled in the art can obtain other drawings according to these drawings without creative efforts.

FIG. 1 is a partial cross-sectional view of a display panel according to an embodiment of this disclosure.

FIG. 2 is a top view of a display panel according to an embodiment of this disclosure.

FIG. 3 is a schematic diagram of a display panel according to a first embodiment of this disclosure.

FIG. 4 is a schematic diagram of a display panel according to a second embodiment of this disclosure.

FIG. 5 is a schematic diagram of a display panel according to a third embodiment of this disclosure.

FIG. 6 is a schematic diagram of a display panel according to a fourth embodiment of this disclosure.

FIG. 7 is a partial cross-sectional view of a display panel according to another embodiment of this disclosure.

FIG. 8 is a schematic diagram of a touch layer in the embodiment of FIG. 7.

FIG. 9 is a partial schematic diagram of an electrode layer in a display panel according to a fifth embodiment of this disclosure.

FIG. 10 is a partial schematic diagram of a display panel according to the fifth embodiment of this disclosure.

FIG. 11 is a partial schematic diagram of an electrode layer in a display panel according to a sixth embodiment of this disclosure.

FIG. 12 is a partial schematic diagram of a display panel according to the sixth embodiment of this disclosure.

### DETAILED DESCRIPTION

Exemplary embodiments will now be described more fully with reference to the accompanying drawings. Exemplary embodiments may, however, be embodied in many forms and should not be construed as limited to the embodiments set forth herein. Rather, these embodiments are provided so that this disclosure will be thorough and complete, and will fully convey the concept of exemplary embodiments to those skilled in the art. The same reference numerals in the drawings denote the same or similar structures, and thus their detailed descriptions will be omitted. Furthermore, the drawings are merely schematic illustrations of this disclosure and are not necessarily drawn to scale.

The terms “a”, “an”, “the”, “said” and “at least one” are used to indicate the presence of one or more elements/components/etc.; the terms “comprise/include” and “have” are used to indicate an open inclusion and means that there may be additional elements/components/etc. in addition to the listed elements/components/etc.; the terms “first”, “second” and “third” etc. are only used as a marker, not a limit on the number of its object.

The row direction X and the column direction Y in this disclosure are merely two directions that intersect each other, for example, they may be perpendicular to each other. In the drawings of this disclosure, the row direction X may be horizontal and the column direction Y may be vertical, but this disclosure is not limited thereto. If the display panel is rotated, the actual directions of the row direction X and the column direction Y may change.

The “overlap” of feature A and feature B in this disclosure means that the orthographic projection of feature A on the substrate and the orthographic projection of feature

B on the substrate at least partially overlap with each other. Alternatively, the orthographic projection can also be an orthographic projection on any plane parallel to the extension direction of the driving backplane.

In this disclosure, feature A and feature B are “in the same layer” means that feature A and feature B can be formed at the same time, the two are different discontinuous or continuous regions in the same film layer, and the two are not separated by other film layers in the direction perpendicular to the substrate.

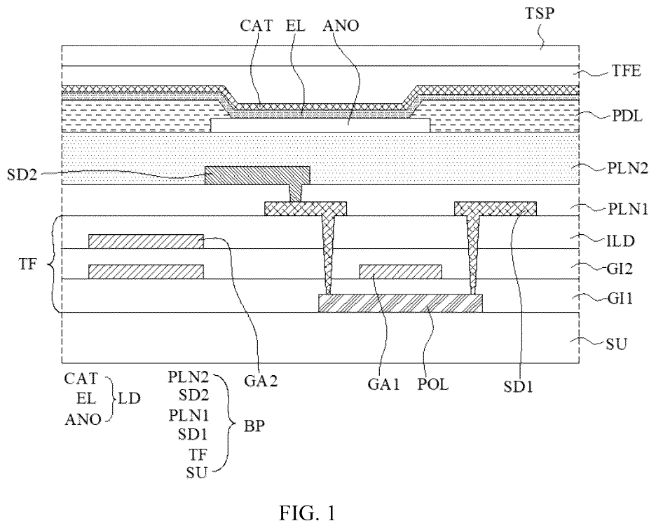

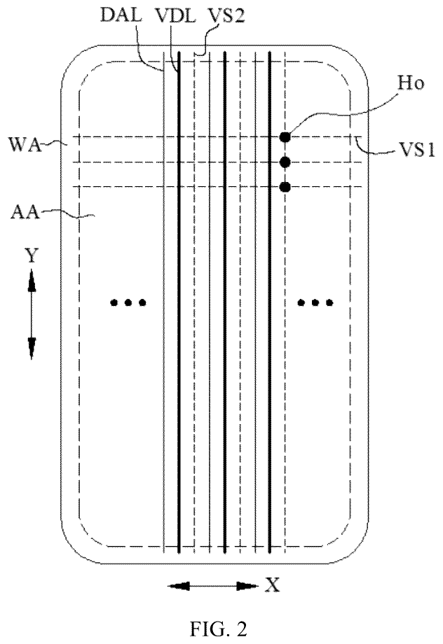

Some embodiments of this disclosure provide a display panel, as shown in FIG. 1, FIG. 2 and FIG. 7, the display panel has a display area AA and a peripheral area WA located outside the display area AA, and the display panel may include a driving backplane BP and a light-emitting device LD.

The driving backplane BP includes a substrate SU and a transistor layer TF, a first conductive layer SD1, a first planarization layer PLN1 and a second conductive layer SD2 which are sequentially provided in a direction away from the substrate SU. The transistor layer TF includes a plurality of transistors. The first conductive layer SD1 includes a first conductive line VS1 which is at least partially located in the display area AA. The second conductive layer SD2 includes a power line VDL and a second conductive line VS2 which are spaced apart from each other, and the power line VDL and the second conductive line VS2 are at least partially located in the display area AA. The second conductive line VS2 is connected to the first conductive line VS1 through a plurality of contact holes Ho which penetrate the first planarization layer PLN1. The power line VDL is configured to transmit a first power signal, and the first conductive line VS1 and the second conductive line VS2 are configured to transmit a second power signal. The contact holes Ho are arranged in a row direction X and a column direction Y, where a spacing between two adjacent contact holes Ho in the row direction X is a first hole spacing D1, and a spacing between two adjacent contact holes Ho in the column direction Y is a second hole spacing D2. There are some contact holes Ho with the same first hole spacing D1 in at least two rows of contact holes Ho, and there are some contact holes Ho with the same second hole spacing D2 in at least two columns of contact holes Ho.

The light-emitting device LD is provided on a side of the second conductive layer SD2 away from the substrate SU and is located in the display area AA. The light-emitting device LD includes a first electrode ANO, a light-emitting layer EL and a second electrode CAT stacked in sequence along the direction away from the substrate SU. The first electrode ANO is connected to at least one transistor through the second conductive layer SD2, and the second electrode CAT is connected to the second conductive line VS2.

In the display panel according to some embodiments of this disclosure, the first conductive line VS1 and the second conductive line VS2 are connected through the contact holes Ho to form a network at least partially located in the display area AA, where the network is configured to transmit two power signals; the power line VDL is configured to transmit the power signal, and the light-emitting device LD can emit light under the action of the first power signal and the second power signal to display an image. Since the power line VDL, the first conductive line VS1 and the second conductive line VS2 are at least partially located in the display area AA, the space of the display area AA can be utilized to provide the lines of the first power signal and the second power signal, thereby reducing or avoiding provision of the lines of the first power signal and the second power signal in the peripheral area WA, which is conducive to reducing size of the peripheral area WA and increasing the screen-to-body ratio, so as to improve the resolution while keeping the size of the display panel unchanged. At the same time, since the space of the display area AA can be fully utilized to provide the network of the first conductive line VS1 and the second conductive line VS2, it is conducive to reducing the voltage drop of the second power signal, thereby reducing power consumption.

In addition, at least two rows of contact holes Ho have some contact holes Ho with the same first hole spacing D1, and at least two columns of contact holes Ho have some contact holes Ho with the same second hole spacing D2, thereby being conducive to making the distribution of the contact holes Ho more uniform, avoiding the display unevenness problem caused by the contact holes Ho, and avoiding the Mura problem.

The following is a detailed description of the disclosed display panel.

As shown in FIG. 2, the display area AA of the display panel is a light-emitting area for displaying images. The peripheral area WA is located outside the display area AA. For example, the peripheral area WA may be a continuous or discontinuous annular area surrounding the display area AA, or may be a semi-enclosed area such as a “U” shape. The shape of the peripheral area WA is not particularly limited.

The display area AA and the peripheral area WA are divided according to their functions, rather than limiting presence of any physical boundary in the display panel for realizing the division.

The driving backplane BP is provided with a driving circuit for driving the light- emitting device LD to emit light. The driving circuit may include a pixel circuit located in the display area AA and a peripheral circuit located in the peripheral area WA.

There are multiple pixel circuits, and they are arranged into multiple rows and columns along the row direction X and the column direction Y. One pixel circuit can be connected to one light-emitting device LD. Alternatively, there may also be a situation where one pixel circuit is connected to multiple light-emitting devices LD. This disclosure only takes the one-to-one connection between the pixel circuit and the light-emitting device LD as an example for explanation.

The pixel circuit may include multiple transistors and capacitors, which may be 3T1C, 7T1C, 8T1C and other pixel circuits. Here, nTmC means that a pixel circuit includes n transistors (indicated by the letter “T”) and m capacitors (indicated by the letter “C”).

The peripheral circuit may be connected to the pixel circuit and the light-emitting device LD, and may control the brightness of the light-emitting device LD by controlling, through the pixel circuit, the current passing through the light-emitting device LD. The peripheral circuit may include a plurality of transistors and capacitors, and may include a gate drive circuit, a light emission controlling circuit and the like. Optionally, it may also include other circuits, and the specific structure of the peripheral circuit is not particularly limited here.

The above pixel circuit may adopt LTPS (low temperature polysilicon) technology, that is, each transistor of the pixel circuit is a LTPS transistor. Optionally, LTPO (LTPS+Oxide) may also be adopted, which is not particularly limited here.

The following is an exemplary description of each film layer in the driving backplane BP.

As shown in FIG. 1 and FIG. 7, the driving backplane BP may include a substrate SU, a transistor layer TF, a first conductive layer SD1, a first planarization layer PLN1 and a second conductive layer SD2.

The substrate SU may be the base of the driving backplane BP, which may carry pixel circuits and peripheral circuits. The substrate SU may be a hard or flexible structure, and may be a single-layer or multi-layer structure, which is not particularly limited herein.

The transistor layer TF is provided on one side of the substrate SU, and may include transistors and capacitors of the driving circuits.

In some embodiments of this disclosure, the transistor layer TF may include a semiconductor layer POL, a first gate insulating layer GI1, a first gate layer GA1, a second gate insulating layer GI2, a second gate layer GA2, and an interlayer dielectric layer ILD sequentially stacked in a direction away from the substrate SU.

The semiconductor layer POL may be provided on one side of the substrate SU and include channels of respective transistors, and the material thereof may be polysilicon.

The first gate insulating layer GI1 may cover the semiconductor layer POL, and the material of the first gate insulating layer GI1 may be an insulating material such as silicon nitride and silicon oxide.

The first gate layer GA1 may be provided on a surface of the first gate insulating layer GI1 away from the substrate SU, and includes gates of respective transistors and first electrode plates of capacitors.

The second gate insulating layer GI2 may cover the first gate layer GA1, and the material thereof may be an insulating material such as silicon nitride and silicon oxide.

The second gate layer GA2 may be provided on a surface of the second gate insulating layer GI2 away from the substrate SU, and includes second electrode plates of the capacitors, where the second electrode plates overlap with the first electrode plates to form the capacitors.

The interlayer dielectric layer ILD may cover the second gate layer GA2, and the material of the interlayer dielectric layer ILD may include an inorganic insulating material such as silicon nitride, silicon oxide, silicon oxynitride, or the like, which is not particularly limited herein.

As shown in FIG. 1 and FIG. 7, the first conductive layer SD1 may be provided on a surface of the interlayer dielectric layer ILD away from the substrate SU, and may be a single-layer or multi-layer structure, and its material may include one or more metals such as Ti, Al, Mg, Ag, etc. For example, the first conductive layer SD1 may include a first sublayer, a second sublayer, and a third sublayer stacked in sequence in a direction away from the substrate SU, where the first sublayer and the third sublayer may be made of the same metal material, such as Ti, and the second sublayer may be made of a metal material different from that of the first sublayer and the third sublayer, such as A1.

The first planarization layer PLN1 may be provided on a side of the first conductive layer SD1 away from the substrate SU, and its material may be an insulating material such as resin. In addition, the display panel may further include a passivation layer, which may cover the first conductive layer SD1, and the first planarization layer PLN1 covers the passivation layer. Alternatively, the first planarization layer PLN1 may also directly cover the first conductive layer SD1.

The second conductive layer SD2 may be provided on a surface of the first planarization layer PLN1 away from the substrate SU, and may be a single-layer or multi-layer structure, and its material may include one or more metals such as Ti, Al, Mg, Ag, etc. For example, the second conductive layer SD2 may be a three-layer structure identical to the first conductive layer SD1.

As shown in FIG. 1 and FIG. 7, the second conductive layer SD2 may include a plurality of power lines VDL, where the power lines VDL may extend along the column direction Y, and at least a portion of any power line VDL is located in the display area AA. The respective power lines VDL may be spaced apart along the row direction X, and each column of pixel circuits may be connected to one of the power lines VDL, where a first power signal may be transmitted to the pixel circuit through the power line VDL. Accordingly, the second conductive layer SD2 may also include a plurality of data lines DAL, and at least a portion of any data line DAL is located in the display area AA. The respective power lines VDL may be spaced apart from the power lines VDL along the row direction X, and each column of pixel circuits may be connected to one of the data lines DAL, where a data signal may be transmitted to the pixel circuit through the data line DAL, so as to control the brightness of the light-emitting device LD.

In addition, the display panel may further include a second planarization layer PLN2, which may cover the second conductive layer SD2, and the material thereof may be an insulating material such as resin.

In other embodiments of this disclosure, the driving backplane BP may further include other conductive layers located on a side of the transistor layer TF away from the substrate SU, and the first conductive layer SD1 and the second conductive layer SD2 may be two of these conductive layers farthest from the substrate SU.

As shown in FIG. 1 and FIG. 7, respective light-emitting devices LD may be provided on one side of the driving backplane BP, for example, the light-emitting devices LD may be provided on a surface of the second planarization layer PLN2 away from the substrate SU. The respective light-emitting devices LD are located in the display area AA, and the light-emitting devices LD may be OLEDs (organic light emitting diodes), Micro LEDs (micrometer LEDs), Mini LEDs (sub-millimeter LEDs), QLEDs (quantum dot diodes), or the like.

For example, the light-emitting device LD may include a first electrode ANO, a light-emitting layer EL, and a second electrode CAT stacked in a direction away from the driving backplane BP. The first electrode ANO may be provided on one side of the driving backplane BP and distributed in an array, for example, the first electrode ANO may be provided on a surface of the second planarization layer PLN2 away from the substrate SU. The first electrode ANO is connected to the pixel circuits. The light-emitting layer EL may include a hole injection layer, a hole transport layer, a light-emitting material layer, an electron transport layer, and an electron injection layer stacked in a direction away from the driving backplane BP. The respective light-emitting devices LD may share the second electrode CAT, that is, the second electrode CAT may be a continuous whole-layer structure.

The second electrode CAT may be connected to a power bus in the peripheral area WA, and the power bus may be connected to the first conductive line VS1 and the second conductive line VS2, so that the second power signal can be applied to the second electrode CAT through the power bus. Alternatively, the second electrode CAT may also be directly connected to the second conductive line VS2 through a via hole in the display area AA. This disclosure does not specifically limit the connection manner between the second electrode CAT and the first and second conductive line VS1, VS2, as long as the first conductive line VS1 and the second conductive line VS2 can be connected to the second electrode CAT.

In addition, as shown in FIG. 1 and FIG. 7, in order to limit the light-emitting range of the light-emitting device LD and prevent crosstalk, a pixel definition layer PDL may be provided on a surface where the first electrode ANO is provided, and the pixel definition layer PDL is located in the display area AA and may be provided with openings exposing the respective first electrode ANOs. The light-emitting layer EL is stacked with the first electrode ANO in the opening. For example, the pixel definition layer PDL and the first electrode ANO are both provided on a surface of the second planarization layer PLN2 away from the substrate SU. The opening of the pixel definition layer PDL may be smaller than the first electrode ANO exposed therein. Since the light-emitting layer EL is a whole-layer structure, the light-emitting layer EL not only stacks with the first electrode ANO in the opening, but also covers the pixel definition layer PDL.

The light-emitting material layers of different light-emitting devices LD are spaced apart from each other, so that the light-emitting device LD can directly emit monochromatic light, and the light-emitting colors of different light-emitting devices LD can be different, thereby realizing color display. Alternatively, the light-emitting material layers of the respective light-emitting devices LD can also be a continuous whole-layer structure, so that the light-emitting colors of the respective light-emitting devices LD are the same, and color display can be realized by cooperating with the filter layer CFL located on a side of the light- emitting device LD away from the driving backplane BP.

In addition, as shown in FIG. 1 and FIG. 7, in some embodiments of this disclosure, the display panel may further include an encapsulation layer TFE and a touch layer TSP.

The encapsulation layer TFE may cover the light-emitting device LD, which may be configured to block external water and oxygen and prevent corrosion to the light-emitting device LD. For example, the encapsulation layer TFE can be encapsulated by thin film encapsulation, which may include a first inorganic layer, an organic layer and a second inorganic layer. The first inorganic layer covers the light-emitting device LD, for example, the first inorganic layer may cover the second electrode CAT. The organic layer may be provided on a surface of the first inorganic layer away from the driving backplane BP, and the boundary of the organic layer is limited to the inner side of the boundary of the first inorganic layer, and the boundary of an orthographic projection of the organic layer on the driving backplane BP may be located in the peripheral area WA, thereby ensuring that the organic layer can cover the respective light-emitting devices LD. The second inorganic layer may cover the organic layer and the first inorganic layer not covered by the organic layer, where the intrusion of water and oxygen can be blocked by the second inorganic layer, and planarization can be achieved by the flexible organic layer.

As shown in FIG. 1 and FIG. 7, the touch layer TSP may be provided on a side of the encapsulation layer TFE away from the driving back plate BP, for example, the touch layer TSP may be provided on a surface of the encapsulation layer TFE away from the driving back plate BP. The touch layer TSP is at least partially located in the display area AA.

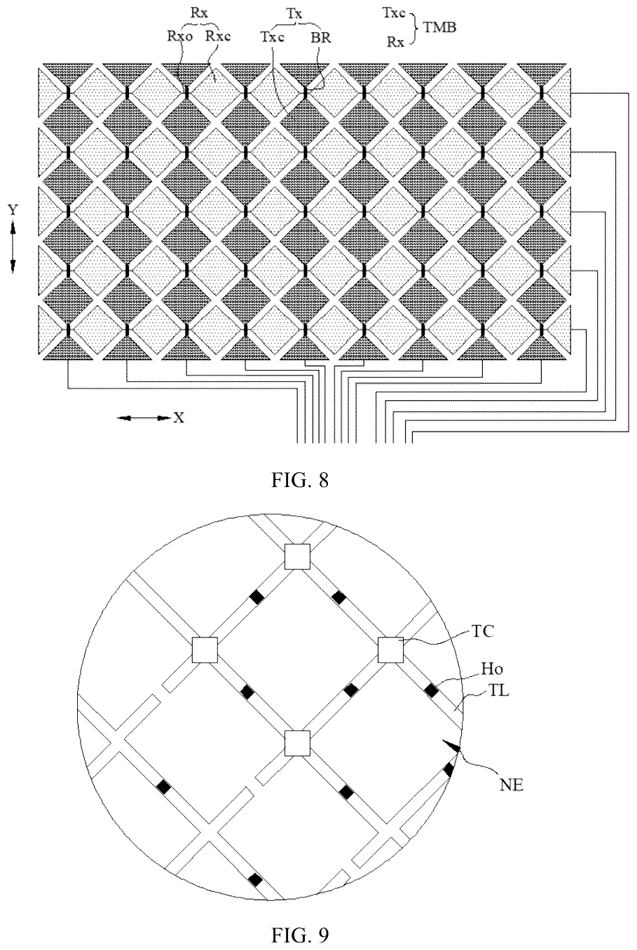

As shown in FIG. 7 and FIG. 8, in some embodiments of this disclosure, the touch layer may be a mutual capacitance structure, which may include a plurality of first touch electrodes Tx and a plurality of second touch electrodes Rx. The respective first touch electrodes Tx may be spaced apart along the row direction X, and the respective second touch electrodes Rx may be spaced apart along the column direction Y. The first touch electrodes Tx and the second touch electrodes Rx may each include a plurality of electrode blocks connected in series. Any first touch electrode Tx may include a plurality of first electrode blocks Txc connected in series along the column direction Y, and any two adjacent first electrode blocks Txc may be connected in series via a connecting bridge BR. Any second touch electrode Rx may include a plurality of second electrode blocks Rxc connected in series along the row direction X, and any two adjacent second electrode blocks Rxc may be connected in series via a connecting part Rxo.

The first electrode blocks Txc and the second electrode blocks Rxc are distributed in an array. At least some of the first electrode blocks Txc are arranged adjacent to different second electrode blocks Rxc in two different directions intersecting the row direction X and the column direction Y. Correspondingly, at least some of the second electrode blocks Rxc are arranged adjacent to different first electrode blocks Txc in two different directions intersecting the row direction X and the column direction Y.

There is a gap between the first electrode block Txc and the second electrode block Rxc that are adjacent to each other, thereby forming a capacitor. When a finger performs a touch operation, the capacitance of the touch position can change. The touch position can be determined by sensing a first touch electrode Tx and a second touch electrode Rx corresponding to the change in capacitance. The detailed principle will not be described in detail here.

The above-mentioned electrode blocks and connecting parts Rxo may be located in the same electrode layer TMB, and the electrode layer TMB may be formed simultaneously through a single patterning process, that is, the electrode layer TMB includes the first electrode block Txc and the second touch electrode Rx. In order to avoid a short circuit between the first touch electrode Tx and the second touch electrode Rx, the connecting bridge BR may be located on one side of the electrode layer TMB, that is, the connecting bridge BR and the electrode layer TMB are not on the same layer. Moreover, the connecting bridge BR and the electrode layer TMB may be separated by an isolation layer IN, and the first touch electrode Tx may cross the second touch electrode Rx at the connecting bridge BR, and further, the connecting bridge BR may cross the connecting part Rxo. In addition, the connecting bridge BR may be connected to the first electrode block Txc through a via Ht that penetrates the isolation layer IN. The material of the isolation layer IN may be silicon nitride, and alternatively, it may also be silicon oxide, silicon oxynitride or other insulating materials.

In addition, as shown in FIG. 7, in some embodiments of this disclosure, the touch layer TSP may further include a buffer layer TBA and a protective layer TOC, where the buffer layer TBA may be provided on a side of the encapsulation layer TFE away from the substrate SU, and its material may include insulating materials such as silicon nitride and silicon oxide. The connecting bridge BR may be provided on a surface of the buffer layer TBA away from the driving backplane BP, and the isolation layer IN covers the connecting bridge BR. The electrode layer TMB is provided on a surface of the isolation layer IN away from the substrate SU. The protective layer TOC may cover the electrode layer TMB and an area of the isolation layer IN not covered by the electrode layer TMB. The protective layer TOC is configured to protect the electrode layer TMB, and its material may be a transparent insulating material such as polyimide (PI) or optical glue.

As shown in FIG. 9 to FIG. 12, in order to reduce the obstruction of the light-emitting device LD, the first touch electrode Tx, the second touch electrode Rx and the connecting bridge BR can be a grid structure formed by grid lines, with respective grid lines extending along a straight line, but the extending direction may be different. The grid lines corresponding to the electrode layer TMB (including the first electrode block Txc and the second touch electrode Rx) are electrode lines TL, and the grid lines corresponding to the connecting bridge BR are connecting lines BL. The aforementioned grid structure has a plurality of meshes NE, with each mesh NE being surrounded by a plurality of grid lines. For example, any mesh NE of the electrode layer TMB may be surrounded by a plurality of electrode lines TL, and any mesh NE of the connecting bridge BR may be surrounded by a plurality of connecting lines BL. The mesh NE may be polygonal, for example, a rhombus, a hexagon, or the like, which is not specifically limited here. Each side of the polygon is a grid line.

As shown in FIG. 9 to FIG. 12, in some embodiments of this disclosure, in order to facilitate formation of the via Ht connecting the first electrode block Txc and the connecting bridge BR, the via Ht may be located at the intersection of the grid lines. By increasing the area of the intersection, the space for accommodating the via Ht can be increased to avoid the via Ht being too small and increasing the resistance. Specifically, at least some adjacent connecting lines BL may be connected through a connecting intersection BC, and a width of the connecting intersection BC may be greater than a width of the connecting line BL connected thereto, where the width of the connecting intersection BC is the maximum distance of the boundary of the connecting intersection BC in the direction perpendicular to the connecting line BL connected thereto. At least some adjacent electrode lines TL are connected through an electrode intersection TC, and a width of the electrode intersection TC is greater than a width of the electrode line TL connected thereto, where the width of the electrode intersection TC is the maximum distance of the boundary of the electrode intersection TC in the direction perpendicular to the electrode line TL connected thereto. For example, the widths of the electrode line TL and the connecting line BL may both be 3.5 μm.

Each connecting intersection BC may overlap with an electrode intersection TC, and the orthographic projections of the two on the substrate SU may coincide with each other. Each connecting intersection BC may be connected to an electrode intersection TC through a via Ht.

In order to reduce the voltage drop of the second power signal and narrow the peripheral area WA, as shown in FIG. 2 and FIG. 7, the first conductive line VS1 may be provided in the first conductive layer SD1, and the second conductive line VS2 may be provided in the second conductive layer SD2, where the first conductive line VS1 is at least partially located in the display area AA and may extend along the row direction X. The number of the first conductive lines VS1 is multiple, which may be spaced apart along the column direction Y. The second conductive line VS2 is at least partially located in the display area AA and may extend along the column direction Y. The number of the second conductive lines VS2 is multiple, which may be spaced apart along the row direction X.

As shown in FIG. 2, in some embodiments of this disclosure, the data line DAL and the power line VDL connected to the same column of pixel circuits form a line group. At least some of the second conductive lines VS2 and line groups are alternately distributed along the row direction X, thereby improving the distribution uniformity of the second conductive lines VS2.

The second conductive line VS2 may be connected to the first conductive line VS1 through a plurality of contact holes Ho penetrating the first planarization layer PLN1, so as to form a network for transmitting the second power signal to the second electrode CAT by utilizing the space in the display area AA, thereby eliminating the need for providing a power bus for transmitting the second power signal to the second electrode CAT in the peripheral area WA, which is beneficial to narrowing the peripheral area WA. At the same time, the network formed by the first conductive line VS1 and the second conductive line VS2 can reduce resistance and thus reduce voltage drop compared to simple routing, which is beneficial to reducing power consumption.

In addition, other conductive film layers may be provided in the display panel and connected to the first conductive line VS1 and the second conductive line VS2, so as to further reduce the resistance and thus the power consumption.

Based on the above embodiments, the inventors found that if multiple contact holes Ho are provided in the display area AA, the display effects of an area where the contact holes Ho are located and an area without the contact holes Ho may be different, and the distribution layout of the contact holes Ho will lead to uneven display, that is, the Mura problem. In order to solve this problem, the inventors proposed two concepts.

The first concept to eliminate the Mura problem is to reduce or eliminate the uniformity problem by designing the arrangement of the contact holes Ho. The following example is given.

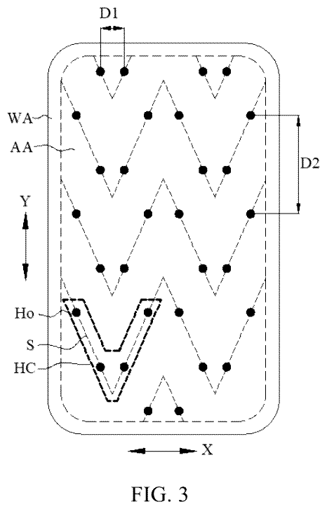

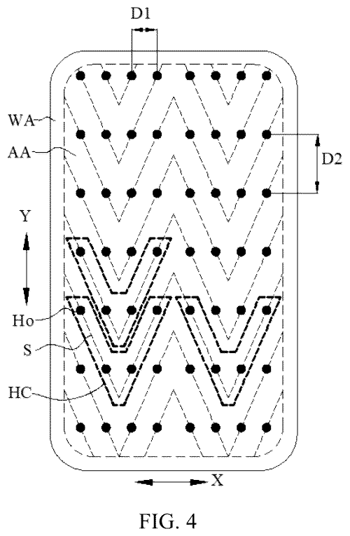

As shown in FIG. 3 and FIG. 4, in the first embodiment of this disclosure, at least some contact holes Ho may be divided into a plurality of hole groups HC, and the respective hole groups HC may be arranged in a plurality of rows along the column direction Y. Each hole group HC may include a plurality of contact holes Ho. The contact holes Ho of each hole group HC are distributed along a zigzag track S, and the zigzag track S may be formed by connecting a plurality of line segments, where the angles between adjacent line segments are acute or obtuse. For example, the zigzag track S may be a V-shaped track, a U-shaped track, or the like. Alternatively, the contact holes Ho in each hole group HC may also be distributed along a straight track or other tracks, which are not particularly limited here.

The spacing between two adjacent contact holes Ho in the row direction X and the column direction Y is the hole spacing, where the hole spacing in the row direction X is the first hole spacing D1, and the hole spacing in the column direction Y is the second hole spacing D2. There are some contact holes Ho with the same first hole spacing D1 in at least two rows of contact holes Ho, and there are some contact holes Ho with the same second hole spacing D2 in at least two columns of contact holes Ho, so as to improve the distribution uniformity of the contact holes Ho.

As shown in FIG. 3, the contact holes Ho in each hole group HC may be distributed along a V-shaped track. The V-shaped track may include two intersecting sides, and both sides intersect the row direction X and the column direction Y. The contact holes Ho in each hole group HC may be symmetrically distributed along the two sides, where the symmetry axis may extend along the column direction Y. Furthermore, the V-shaped tracks of respective hole groups HC in the same row of hole groups HC may be connected to form a W-shaped track.

Further, as shown in FIG. 4, in a second embodiment of this disclosure, the contact holes Ho in each hole group HC may be distributed into multiple rows along the column direction Y, the number of contact holes Ho in a row of each hole group HC is two, and the two contact holes Ho in the same row are respectively located on the two sides of a V-shaped track. In some embodiments, the contact holes Ho in the k-th row of the hole group in the n-th row and the i-th column are located in the same row as the contact holes Ho in the first row of the hole group in the (n+1)-th row and the i-th column, that is, the contact holes Ho in the same row may belong to hole groups HC located in different rows. At the same time, the contact holes Ho in the first row of the hole group in the n-th row and the i-th column are located between the two contact holes Ho in the k-th row of the hole group in the (n+1)-th row and the i-th column. The aforementioned n, i and k are all positive integers, and k is greater than 1. For example, i is equal to 1, k is equal to 2. Each hole group HC has 4 contact holes Ho that are distributed along two sides of the V-shaped track, with 2 contact holes Ho being distributed on each side. The contact holes Ho in the second row of the hole group in the n-th row and the first column are located in the same row as the contact holes Ho in the first row of the hole group in the (n+1)-th row and the first column. The contact holes Ho in the second row of the hole group in the n-th row and the first column are located between the two contact holes Ho in the first row of the hole group in the first column and the (n+1)-th row.

In this way, the first hole spacings D1 of the contact holes Ho in the same row can be made the same, and the second hole spacings D2 of the contact holes Ho in the same column can be made the same.

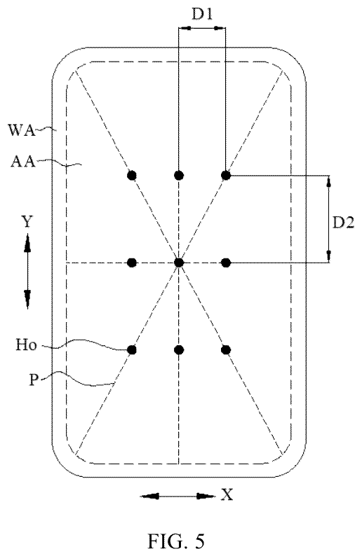

As shown in FIG. 5, in the third embodiment of this disclosure, at least some contact holes Ho may be distributed along a plurality of straight tracks P that are radially distributed and intersect at the same intersection, where the number of the straight tracks P may be two, three, four or more. For example, the number of the straight tracks P is four, where one straight track P extends along the row direction X, one straight track P extends along the column direction Y, and the other straight tracks P may intersect the row direction X and the column direction Y.

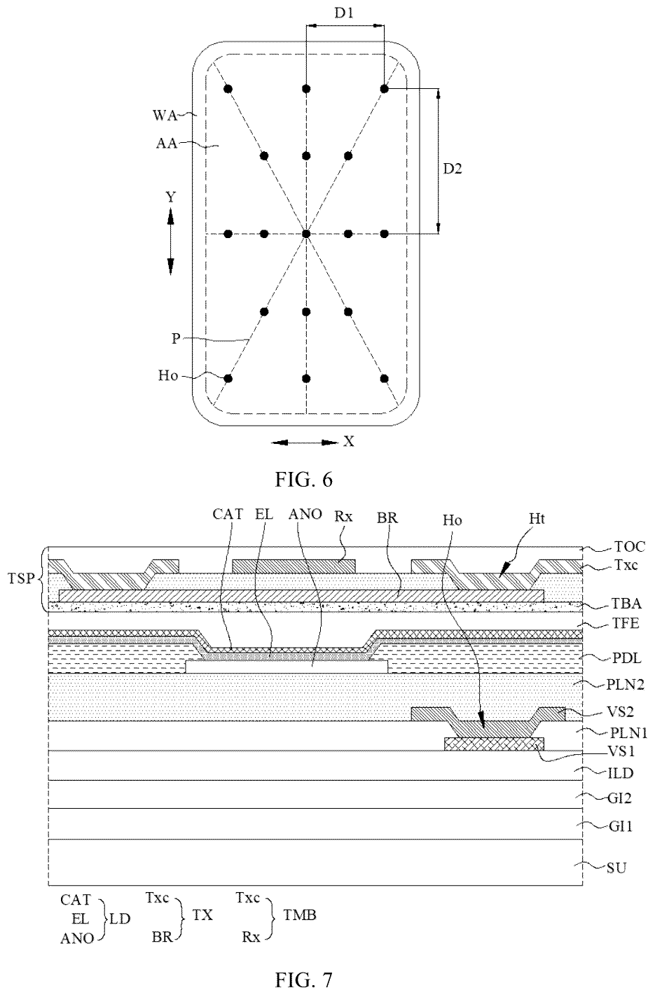

Further, as shown in FIG. 6, in the fourth embodiment of this disclosure, each straight track P is provided with a plurality of contact holes Ho, and the numbers of contact holes Ho on respective straight tracks P are the same. The first hole spacings D1 of the contact holes Ho in the same row can be the same, and the second hole spacings D1 of the contact holes Ho in the same column can be the same.

In other embodiments of this disclosure, at least some contact holes Ho may also be distributed along a plurality of polygonal tracks that are concentrically arranged, with each vertex and midpoint of each side of each polygonal track may be provided with one contact hole Ho. Moreover, the centers of respective polygonal tracks may be the same point, and the center may also be provided with one contact hole Ho. The shapes of respective polygonal tracks may be the same or different, for example, each polygonal track is a rectangle.

The second concept of eliminating the Mura problem is to shield the contact holes Ho through the touch layer TSP, thereby visually eliminating the Mura problem caused by uneven distribution of the contact holes Ho.

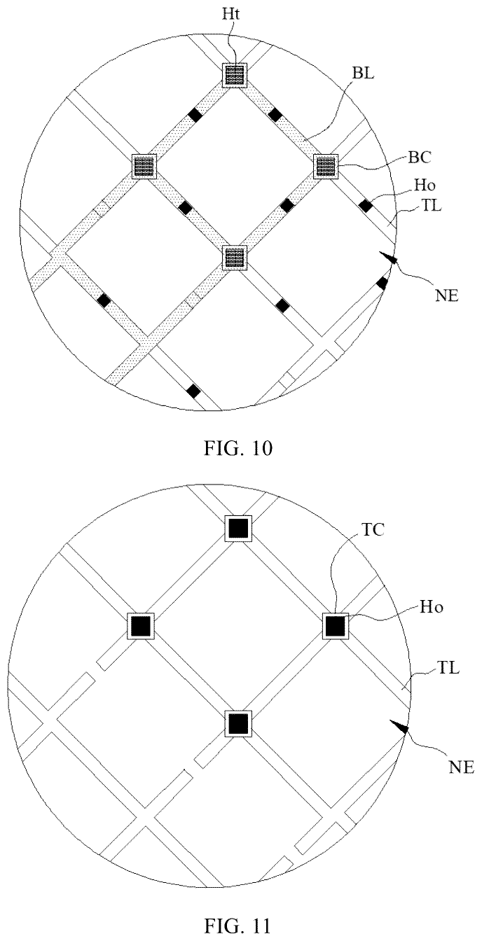

As shown in FIG. 9 and FIG. 10, in the fifth embodiment of this disclosure, based on the structure of the touch layer TSP described above, at least some contact holes Ho may overlap with the grid lines. The orthographic projection of some contact holes Ho on the substrate SU at least partially overlaps with, and thereby being blocked by, the orthographic projection of the grid lines corresponding to the first touch electrode Tx or the second touch electrode Rx on the substrate SU. Alternatively, the orthographic projection of the contact holes Ho on the substrate SU may be located within, thereby being completely blocked by, the orthographic projection of the grid lines overlapping with the contact holes on the substrate SU, where the grid lines may be the electrode lines TL or the connecting lines BL.

For one contact hole Ho, its orthographic projection on the substrate SU may be located between two ends of the orthographic projection of a grid line on the substrate SU, that is, the grid line blocks the contact hole Ho through the area between the two ends. A single grid line may block one, two or more contact holes Ho, which is not particularly limited here.

Alternatively, a contact hole Ho can also be blocked by an electrode line TL and a connecting line BL, that overlap with each other, at the same time, that is, the orthographic projections of the electrode line TL and the connecting line BL on the substrate SU coincide with each other, and the orthographic projection of the contact hole Ho on the substrate SU is located within the orthographic projections of the electrode line TL and the connecting line BL on the substrate SU.

Further, as shown in FIG. 9 and FIG. 10, the orthographic projection of the contact hole Ho on the substrate SU is a polygon, which may be a square, a rectangle, a rhombus, a pentagon, or the like. At least one side of the polygon is parallel to one side of the orthographic projection, on the substrate SU, of the grid line on which the polygon is located. The grid line may be configured in such a manner that the boundary of the contact hole Ho can be as close as possible to the boundary of the grid line while ensuring that the grid line can shield the contact hole Ho, thereby preventing the contact hole Ho from being too small and helping to reduce resistance. Alternatively, the shape of the orthographic projection of the contact hole Ho on the substrate SU may also be a circle, an ellipse, or the like.

Further, the contact hole Ho is a square hole, that is, its orthographic projection on the substrate SU is a square, and the two opposite sides of its orthographic projection may be parallel to two sides of the orthographic projection of the grid line on the substrate SU. The width of the grid line may be 3 μm to 4 μm, and the side length of the orthographic projection of the contact hole Ho on the substrate SU is less than the width of the grid line. For example, the width of the grid line is 3.5 μm, and the side length of the orthographic projection of the contact hole Ho on the substrate SU is 3 μm.

It should be noted that those skilled in the art may know that, due to factors such as manufacturing process, material properties and the like, the shape of the contact hole Ho (the shape of the orthographic projection thereof on the substrate SU) mentioned above may have certain errors and is not necessarily a standard geometric shape. For example, the sides of the polygon are not necessarily standard straight lines, and there may be bends within the error range. If the shape of the contact hole Ho is a regular polygon, the lengths of its sides may have certain differences. For example, the shape of the contact hole Ho is a square, but the lengths of different sides of the square may have errors, and the angle between two adjacent sides may not necessarily be 90°.

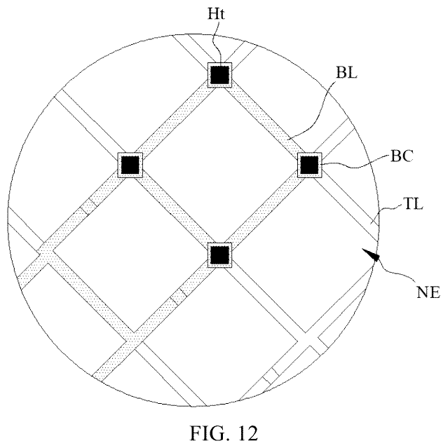

As shown in FIG. 11 and FIG. 12, in the sixth embodiment of this disclosure, the contact hole Ho can be shielded by the connecting intersection BC and the electrode intersection TC. Since the widths of the electrode intersection TC and the connecting intersection BC are greater than the width of the grid line connected thereto, a larger contact hole Ho can be shielded compared to the grid line, which is beneficial to increase the contact hole Ho. Each contact hole Ho may overlap with one connecting intersection BC and one electrode intersection TC, where the connecting intersection BC and the electrode intersection TC may be connected through the via Ht, that is, the contact hole Ho may overlap with the via Ht. Due to the coverage of the first planarization layer PLN1, the second planarization layer PLN2, the pixel definition layer PDL and the encapsulation layer TFE, the contact hole Ho can be planarized without affecting the formation of the upper film layer(s).

It should be noted that the two concepts and related implementations proposed above can be used alone or in combination. For example, the contact holes Ho can be distributed in the V-shaped track described above, and can also be blocked by the grid lines, the connecting intersections BC and the electrode intersections TC. Alternatively, some contact holes Ho are blocked by the connecting intersections BC and the electrode intersections TC block, and some other contact holes Ho are blocked by the grid lines. The combination manners will not be elaborated here.

Some embodiments of this disclosure further provide a display device, which may include the display panel according to any of the forgoing embodiments. As to the specific structure and beneficial effects of the display panel, the forgoing embodiments of the display panel can be referred to, which will not be described in detail here.

The display device disclosed in this disclosure may be an electronic device with display function, such as a mobile phone, a tablet computer, a head-mounted display device, or the like. When the display panel has a touch layer TSP, the display device can also sense touch operations to achieve human-computer interaction, which will not be elaborated here.

Other embodiments of this disclosure will be readily apparent to those skilled in the art from consideration of the specification and practice of the invention disclosed herein. This application is intended to cover any modification, use or adaptation of this disclosure, and these modifications, uses or adaptations follow the general principles of this disclosure and include common knowledge or conventional technical means in the technical field not disclosed in this disclosure. The specification and examples are to be considered exemplary only, with the true scope and spirit of the disclosure indicated by the appended claims.

1. A display panel, having a display area and a peripheral area outside the display area, comprising:
a driving backplane, comprising a substrate and a transistor layer, a first conductive layer, a first planarization layer and a second conductive layer sequentially provided in a direction away from the substrate; wherein the transistor layer comprises a plurality of transistors; the first conductive layer comprises a first conductive line at least partially located in the display area; the second conductive layer comprises a power line and a second conductive line spaced from each other, and both the power line and the second conductive line are at least partially located in the display area; the second conductive line is connected to the first conductive line through a plurality of contact holes penetrating the first planarization layer; the power line is configured to transmit a first power signal, and the first conductive line and the second conductive line are configured to transmit a second power signal; the contact holes are arranged in a row direction and a column direction, a spacing between any two adjacent contact holes in the row direction is a first hole spacing, and a spacing between any two adjacent contact holes in the column direction is a second hole spacing; some contact holes have the same first hole spacing in at least two rows of contact holes, and some contact holes have the same second hole spacing in at least two columns of contact holes; and
a light-emitting device, provided on a side of the second conductive layer away from the substrate and located in the display area; wherein the light-emitting device comprises a first electrode, a light-emitting layer and a second electrode stacked in sequence in the direction away from the substrate; the first electrode is connected to at least one of the transistors through the second conductive layer, and the second electrode is connected to the second conductive line.

2. The display panel according to claim 1, wherein at least some of the contact holes are divided into a plurality of hole groups, and the respective hole groups are arranged in a plurality of rows along the column direction;
one of the hole groups comprises some of the contact holes, and the contact holes in the one of the hole groups are arranged along a zigzag track.

3. The display panel according to claim 2, wherein the contact holes in the one of the hole groups are arranged along a V-shaped track.

4. The display panel according to claim 3, wherein the V-shaped track comprises two intersecting sides, and both of the two sides intersect with the row direction and the column direction; and the contact holes in the one of the hole groups are symmetrically distributed along the two sides.

5. The display panel according to claim 4, wherein the contact holes in the one of the hole groups are distributed into a plurality of rows along the column direction, and a number of contact holes in one row in the one of the hole groups is two;
a contact hole in k-th row of a hole group in n-th row and i-th column is located in a same row as two contact holes in 1st row of a hole group in (n+1)-th row and i-th column, and the contact hole in the k-th row of the hole group in the n-th row and i-th column is located between the two contact holes in the 1st row of the hole group in the (n+1)-th row and i-th column;
where n, i and k are all positive integers, and k is greater than 1.

6. The display panel according to claim 1, wherein at least some of the contact holes are arranged along a track formed by a plurality of radially distributed straight lines intersecting at a same intersection.

7. The display panel according to claim 6, wherein each of the straight lines is provided with multiple ones of the contact holes, and numbers of contact holes on each of the straight lines are the same.

8. The display panel according to claim 1, wherein the first hole spacings of contact holes in a same row are the same.

9. The display panel according to claim 1, wherein the second hole spacings of contact holes in a same column are the same.

10. The display panel according to claim 1, further comprising:
a touch layer, provided on a side of the light-emitting device away from the substrate; wherein the touch layer comprises a plurality of touch electrodes, and the touch electrodes are in a grid structure formed by a plurality of grid lines;
wherein at least some of the contact holes overlap with the grid lines.

11. The display panel according to claim 10, wherein the touch electrodes comprise a plurality of first touch electrodes and a plurality of second touch electrodes, the respective first touch electrodes are spaced apart along the row direction, and one of the first touch electrodes comprises a plurality of first electrode blocks spaced apart along the column direction and a connecting bridge connecting any adjacent two of the first electrode blocks; the respective second touch electrodes are spaced apart along the column direction, and one of the second touch electrodes comprises a plurality of second electrode blocks connected in series along the row direction; one of the connecting bridges is arranged crosswise with one of the second touch electrodes; the first electrode blocks and the second electrode are located in a same electrode layer; and the connecting bridges are located on one side of the electrode layer;
the touch layer further comprises a touch insulating layer located between the connecting bridges and the electrode layer, and the connecting bridges are connected to the first electrode blocks through a via hole penetrating the touch insulating layer.

12. The display panel according to claim 11, wherein an orthographic projection of a contact hole on the substrate is located within an orthographic projection, on the substrate, of a grid line overlapping with the contact hole.

13. The display panel according to claim 12, wherein the orthographic projection of the contact hole on the substrate is a polygon, and at least one side of the polygon is parallel to a side of the orthographic projection, on the substrate, of the grid line, wherein the polygon is located at the grid line.

14. The display panel according to claim 13, wherein the orthographic projection of the contact hole on the substrate is a square, and a side length of the square is smaller than a width of the grid line.

15. The display panel according to claim 11, wherein the first electrode blocks and the second electrode blocks are located on a side of the connecting bridges away from the substrate;
grid lines corresponding to the connecting bridges are connecting lines, and grid lines corresponding to the first electrode blocks and the second electrode blocks are electrode lines; at least some adjacent ones of the connecting lines are connected through a connecting intersection, and a width of the connecting intersection is greater than a width of the connecting line connected to the connecting intersection; at least some adjacent ones of the electrode lines are connected through an electrode intersection, and a width of the electrode intersection is greater than a width of the electrode line connected to the electrode intersection; the connecting intersection is connected to the electrode intersection through the via hole;
one of the contact holes overlaps with the connecting intersection and the electrode intersection.

16. The display panel according to claim 1, wherein the second conductive layer further comprises a data line; the data line, the power line and the second conductive line all extend along the column direction and are spaced apart along the row direction;
the driving backplane comprises a plurality of pixel circuits distributed along the row direction and the column direction, and the pixel circuit comprises a plurality of the transistors;
one column of the pixel circuits overlaps with and is connected to the data line and the power line;
the data line and the power line connected to the pixel circuits in a same column form a line group, and at least some of the second conductive lines and the line group are alternately distributed along the row direction.

17. A display device, comprising a display panel, wherein the display panel, having a display area and a peripheral area outside the display area, comprises:
a driving backplane, comprising a substrate and a transistor layer, a first conductive layer, a first planarization layer and a second conductive layer sequentially provided in a direction away from the substrate; wherein the transistor layer comprises a plurality of transistors; the first conductive layer comprises a first conductive line at least partially located in the display area; the second conductive layer comprises a power line and a second conductive line spaced from each other, and both the power line and the second conductive line are at least partially located in the display area; the second conductive line is connected to the first conductive line through a plurality of contact holes penetrating the first planarization layer; the power line is configured to transmit a first power signal, and the first conductive line and the second conductive line are configured to transmit a second power signal; the contact holes are arranged in a row direction and a column direction, a spacing between any two adjacent contact holes in the row direction is a first hole spacing, and a spacing between any two adjacent contact holes in the column direction is a second hole spacing; some contact holes have the same first hole spacing in at least two rows of contact holes, and some contact holes have the same second hole spacing in at least two columns of contact holes; and
a light-emitting device, provided on a side of the second conductive layer away from the substrate and located in the display area; wherein the light-emitting device comprises a first electrode, a light-emitting layer and a second electrode stacked in sequence in the direction away from the substrate; the first electrode is connected to at least one of the transistors through the second conductive layer, and the second electrode is connected to the second conductive line.
